(19) United States
(12) Patent Application Publication
(10) Pub. No.: US 2010/0258526 A1
(43) Pub. Date: Oct. 14, 2010

(54) METHODS OF FORMING AN AMORPHOUS CARBON LAYER AND METHODS OF FORMING A PATTERN USING THE SAME

(76) Inventors: Jaihyung Won, Seoul (KR); Jin-Hyung Park, Suwon-si (KR); Jeon-Sig Lim, Suwon-si (KR); Jae-Hyun Park, Hwaseong-si (KR); Jong-Sik Choi, Hwaseong-si (KR)

Correspondence Address: MYERS BIGEL SIBLEY & SAJOVEC, PO BOX 37428, RALEIGH, NC, 27627, US

(21) Appl. No.: 12/753,939

(22) Filed: Apr. 5, 2010

(30) Foreign Application Priority Data
Apr. 8, 2009 (KR) 10-20090030419
Feb. 4, 2010 (KR) 10-2010-0010272

(51) Int. Cl. C23F 1/00; C23C 16/44

(52) U.S. Cl. 216/37; 427/577

(57) ABSTRACT

In a method of forming an ACL, a substrate is provided in a deposition chamber. A plasma deposition process is performed by providing a deposition gas into the deposition chamber to form the ACL on the substrate. The deposition gas includes a deposition source gas, a carrier gas and a control gas. The deposition source gas includes a hydrocarbon, and the control gas includes at least one of oxygen and oxycarbon.

### CLAIM OF PRIORITY

This application claims priority under 35 USC §119 to Korean Patent Application Nos. 10-2009-0030419 and 10-2010-0010272, filed on Apr. 8, 2009 and Feb. 4, 2010, respectively, in the Korean Intellectual Property Office (KIPO), the contents of which are herein incorporated by reference in their entirety.

### BACKGROUND

Example embodiments relate to methods of forming an amorphous carbon layer (ACL) and methods of forming a pattern using the same.

As semiconductor devices have been highly integrated, forming a pattern having a minute size is important. When a photoresist pattern is used as an etching mask, the photoresist pattern may not have good etching resistance, and thus a hard mask has been used as the etching mask.

However, when a hard mask is formed on a substrate, the substrate may be under sufficient stress so that the substrate may be bended. Particularly, a substrate having a large diameter of about 300 mm may be seriously bended. Thus, forming a hard mask having good uniformity is not easy.

### SUMMARY

Example embodiments provide methods of forming an amorphous carbon layer (ACL) having low stress on a substrate.

Example embodiments provide methods of forming a pattern using methods of forming an ACL having low stress on a substrate.

According to example embodiments, there is provided a method of forming an amorphous carbon layer (ACL). In the method, a substrate is provided in a deposition chamber. A plasma deposition process is performed by providing a deposition gas into the deposition chamber to form the ACL on the substrate. The deposition gas includes a deposition source gas, a carrier gas and a control gas. The deposition source gas includes a hydrocarbon, and the control gas includes at least one of oxygen and oxycarbon.

In example embodiments, the deposition gas may be provided into the deposition chamber at a flow rate per hour of about 1 to about 20% of a volume of the deposition chamber.

In example embodiments, the deposition source gas and the control gas may be provided into the deposition chamber at a flow rate ratio of about 20:1 to about 2:1.

In example embodiments, the hydrocarbon may include carbon and hydrogen at a ratio of about 1:2 to about 1:5.

In example embodiments, a temperature of the substrate may be controlled so that the substrate may remain flat.

In example embodiments, the oxycarbon may include carbon monoxide or carbon dioxide.

In example embodiments, an amount of the control gas may be controlled so that an extinction coefficient of the ACL may be controlled.

In example embodiments, the amount of the control gas may be increased so that the extinction coefficient of the ACL may increase, or an amount of the oxygen in the control gas may be decreased so that the extinction coefficient of the ACL may decrease.

According to example embodiments, there is provided a method of forming a pattern. In the method, a substrate having an etching-target layer thereon is provided in a deposition chamber. A plasma deposition process is performed at a temperature of about 400 to about 500° C. by providing a deposition gas into the deposition chamber to form an amorphous carbon layer (ACL) on the etching-target layer. The deposition gas includes a deposition source gas, a carrier gas and a control gas. The deposition source gas includes hydrocarbon, and the control gas includes at least one of oxygen and oxycarbon. A photoresist pattern is formed on the ACL. The ACL is partially etched using the photoresist pattern to form an ACL pattern. The etching-target layer is partially etched using the ACL pattern to form the pattern.

In example embodiments, the etching-target layer may include silicon oxide, silicon nitride, single crystalline silicon, silicon oxycarbide, or silicon oxynitride. These may be used alone or in a combination thereof.

According to example embodiments, an ACL having a good uniformity and a controllable etching selectivity may be formed on a substrate without bending the substrate. The ACL may serve as an etching mask or a hard mask for forming minute patterns.

### BRIEF DESCRIPTION OF THE DRAWINGS

FIGS. 1 to 31 represent non-limiting, example embodiments as described herein.

FIG. 1 is a cross-sectional view illustrating a deposition apparatus for forming a carbon layer in accordance with example embodiments;

FIG. 2 is a flowchart illustrating a method of forming a carbon layer in accordance with example embodiments;

FIGS. 3 to 8 are cross-sectional views illustrating a method of forming a pattern in accordance with example embodiments;

FIG. 9 is a graph showing the thicknesses of the ACLs of Example 3 and Comparative Examples 2 and 3;

FIG. 10 is a graph showing the intensity of diamond/graphite (D/G) of the ACLs of Example 3 and Comparative Examples 2 and 3;

FIG. 11 is a graph showing thicknesses of the ACLs of Example 6 and Comparative Example 4 at various positions;

FIG. 12 is a graph showing thicknesses of the eleventh ACLs of Comparative Example 5 (#1 to #7);

FIG. 13 is a graph showing the extinction coefficient of the eleventh ACLs of Comparative Example 5 (#1 to #7);

FIG. 14 is a graph showing the extinction coefficient of the twelfth ACLs of Example 7 (#1 to #7);

FIGS. 15 to 18 are cross-sectional views illustrating a method of forming a pattern in accordance with example embodiments;

FIGS. 19 to 22 are cross-sectional views illustrating a method of forming a pattern in accordance with example embodiments;

FIGS. 23 to 27 are cross-sectional views illustrating a method of manufacturing a DRAM device in accordance with example embodiments;

FIG. 28 is a block diagram illustrating a memory card including the ACL formed by the method in accordance with example embodiments;

FIG. 29 is a block diagram illustrating a portable device including the ACL formed by the method in accordance with example embodiments; and

FIG. 30 is a block diagram illustrating a computer including the ACL formed by the method in accordance with example embodiments; and

FIG. 31 is a block diagram illustrating a semiconductor device including the ACL formed by the method in accordance with example embodiments.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

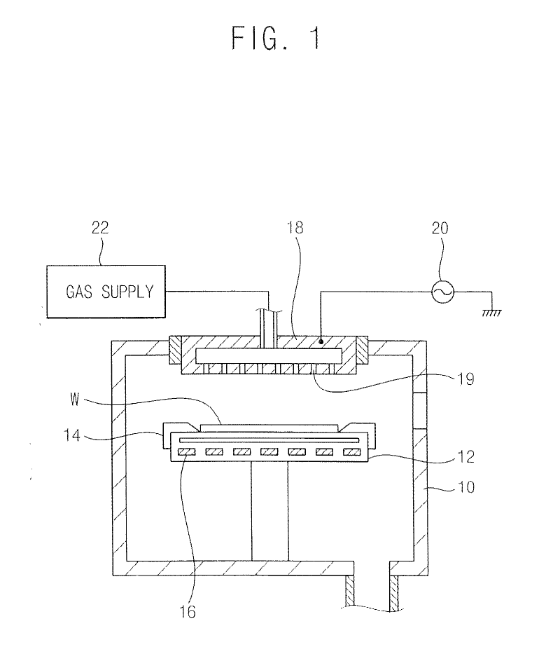

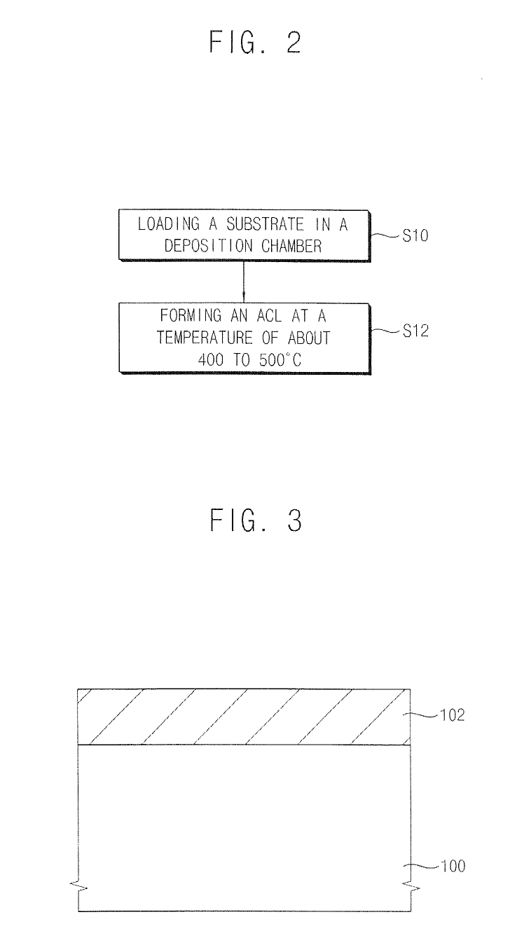

FIG. 1 is a cross-sectional view illustrating a deposition apparatus for forming a carbon layer in accordance with example embodiments.

Referring to FIG. 1, the deposition apparatus may include a deposition chamber 10. The deposition chamber 10 may include a susceptor 12 for supporting a substrate W. A guide ring 14 for guiding the substrate W may be disposed on an edge portion of the susceptor 14. A heater 16 may be disposed in the susceptor 12 and control the temperature of the substrate W.

A shower head 18 may be disposed over the susceptor 12. The shower head 18 may be connected to a gas supply 22 outside the deposition chamber 10. A deposition gas provided by the gas supply 22 may be provided onto the substrate W via gas outlets 19 in the shower head 18. The shower head 18 may be connected to a high frequency power supply 20, and the deposition gas may be in a plasma state by the electric power provided by the power supply 20.

The deposition chamber 10 may further include a vacuum pump (not shown) that may evacuate a remaining deposition gas out of the deposition chamber 10.

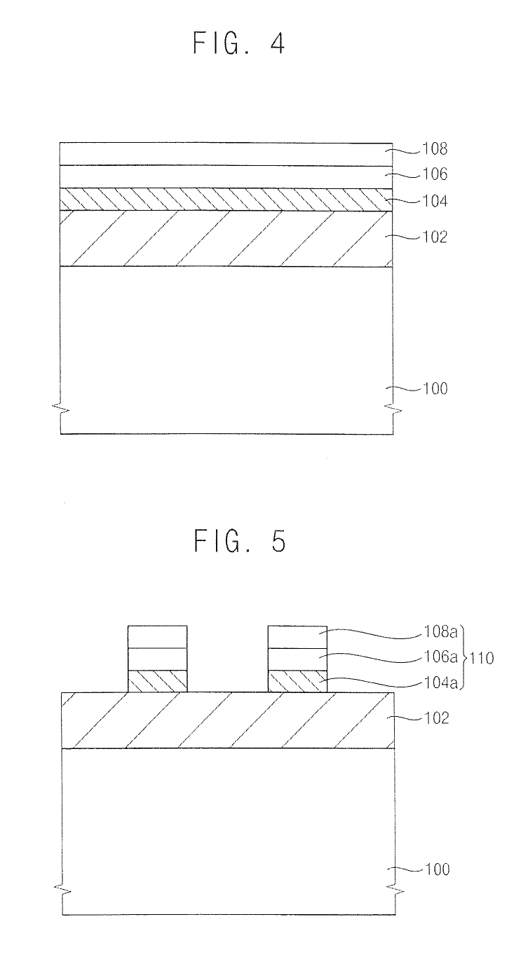

FIG. 2 is a flowchart illustrating a method of forming a carbon layer in accordance with example embodiments.

Referring to FIGS. 1 and 2, in step S10, the substrate W may be provided into the deposition chamber 10. The substrate W may have an object layer (not shown) thereon, which may be etched. The object layer may include silicon oxide, silicon nitride, single crystalline silicon, silicon oxycarbide, silicon oxynitride, etc. The object layer may include a single layer or a multi-stack layer. Alternatively, the substrate W itself may be etched.

The substrate W may be loaded on the susceptor 12 in the deposition chamber 10. The susceptor 12 may be heated to a temperature for a deposition process. In example embodiments, the susceptor 12 may be heated to a temperature of about 400 to about 500° C. An electric power may be applied to the shower head 18 by the power supply 20.

A deposition gas including a deposition source gas, a carrier gas and a control gas may be provided into the deposition chamber 10 in the above temperature range. The deposition source gas may include hydrocarbon (CₓH_{y}), and the control gas may include oxygen and/or oxycarbon. Thus, an amorphous carbon layer (ACL) (not shown) may be formed on the object layer or on the substrate W. That is, when the ACL is formed, the control gas may be provided together with the deposition source gas and the carrier gas.

Hereinafter, a deposition process for forming the ACL may be illustrated in detail.

A deposition temperature for forming the ACL may be in a range of about 400 to about 500° C.

When the deposition temperature is below about 400° C., the ACL may have a large tensile stress, so that the substrate W may bend in a tensile direction. When the deposition temperature is above about 500° C., the ACL may have a large compressive stress, so that the substrate W may bend in a compressive direction.

However, when the deposition temperature is in the range of about 400 to about 500° C., the substrate W may be under reduced stress. Particularly, when the deposition temperature is in a range of about 400 to about 430° C., the substrate W may be under a small tensile stress, thereby being slightly bent in a tensile direction. Additionally, when the deposition temperature is in a range of about 470 to about 500° C., the substrate W may be under a small compressive stress, thereby being slightly bent in a compressive direction. When the deposition temperature is in a range of about 430 to about 470° C., the substrate W may be under a much reduced stress, so that the substrate W may be slightly bent.

Thus, after forming the ACL on the substrate W, the substrate W having even a large diameter of about 300 mm may not bend very much, or may be under no stress, by controlling the deposition temperature of the ACL.

As illustrated above, the deposition source gas may include hydrocarbon (CₓH_{y}), and the control gas including at least one of oxygen and oxycarbon may be further provided. The oxycarbon may include carbon monoxide, carbon dioxide, etc.

In example embodiments, a hydrocarbon gas including carbon and hydrogen at a ratio of about 1:2 to about 1:5 and may serve as the deposition source gas. Ethylene-based hydrocarbon gas, e.g., C₃H₆ gas may be used for the deposition source gas.

The carrier gas may carry the deposition source gas and the control gas to the deposition chamber 10. The carrier gas may include an inactive gas such as helium, argon, etc.

When the deposition source gas, i.e., the hydrocarbon gas and the carrier gas are provided into the deposition chamber 10 at a flow rate ratio of more than about 1:1.5, carbon atoms in the hydrocarbon gas may not be reacted actively. When the hydrocarbon gas and the carrier gas are provided on the substrate W at a flow rate ratio of less than about 1:0.7, the hydrocarbon gas may not be sufficiently carried into the deposition chamber 10. Thus, the hydrocarbon gas and the carrier gas may be provided into the deposition chamber 10 at a flow rate ratio of about 1:0.7 to about 1:1.5.

The control gas may control the type of carbon bondings of an ACL that may be deposited on the substrate W, and thus may control the refractive index and the extinction coefficient of the ACL. The extinction coefficient of the ACL may be related to the etching selectivity thereof. Particularly, when the extinction coefficient decreases, the etching selectivity with respect to an etching-target layer may decrease.

When a flow rate of the control gas increases, the extinction coefficient of the ACL may increase. On the other hand, when the flow rate of the control gas decreases, the extinction coefficient of the ACL may decrease. The extinction coefficient of the ACL may be controlled in a range of about 0.1 to about 1 by changing the flow rate of the control gas. When the extinction coefficient is in the range of about 0.1 to about 1, the hydrocarbon gas and the control gas may have a flow rate ratio of about 20:1 to about 2:1.

Generally, when an ACL has an etching selectivity with respect to both silicon oxide and single crystalline silicon, the ACL may have an extinction coefficient of about 0.41 to about 0.42. In the extinction coefficient range, the hydrocarbon gas and the control gas may have a flow rate ratio of about 5:1 to about 2:1.

The control gas may increase carbon bondings of the ACL during a plasma reaction of the hydrocarbon gas, and thus the ACL may be densified to have a high etching selectivity with respect to the above material.

The layer quality, uniformity, and deposition rate of the ACL may be changed according to a total flow rate of the deposition gas, because an amount of reaction by-products and a recombination ratio of the reaction by-products may be changed according to the total flow rate thereof. Additionally, according to the total flow rate thereof, a vortex may be generated in the deposition chamber 10. Thus, an inflow of the deposition gas may not be uniform throughout the substrate W, and the ACL may have a non-uniform thickness.

When the deposition gas including the deposition source gas, the carrier gas and the control gas has a flow rate per hour higher than 20% of the volume of the deposition chamber 10, the deposition rate of the ACL may decrease. Additionally, the vortex of the deposition gas may be generated to deteriorate the uniformity of the ACL. When the deposition gas has a flow rate per hour lower than 1% of the volume of the deposition chamber 10, the amount of the deposition gas is not enough to form the ACL on the substrate W.

Thus, the flow rate per hour of the deposition gas may be in a range of about 1% to about 20% of the volume of the deposition chamber 10. Preferably, the flow rate per hour of the deposition gas may be in a range of about 5% to about 10% of the volume of the deposition chamber 10.

The deposition gas introduced into the deposition chamber 10 in the deposition process may be pumped out of the deposition chamber 10. Thus, the deposition gas may be maintained in the deposition chamber 10 at a volume of about 1% to about 20% of the volume of the deposition chamber 10.

As described above, when the deposition gas has a flow rate ratio of about 1% to about 20% of the deposition chamber 10, the deposition rate of the ACL may increase and the uniformity thereof may be also improved.

When the flow rate of the deposition gas is low, the amount of the deposition source gas, i.e., the hydrocarbon gas is small, and thus reaction by-products may not be recombined and remain in the ACL. Accordingly, the ACL may have a lot of CH═CH bonds as well as C═C bonds. When the ACL includes a lot of CH═CH bonds, the extinction coefficient may decrease and the etching selectivity with respect to silicon oxide and single crystalline silicon may decrease.

However, when oxygen gas is used as the control gas, the oxygen gas may be reacted with carbon or hydrogen in the deposition source gas, thereby generating a lot of reactants such as CO₂ and H₂O. Thus, the CH═CH bonds in the ACL may decrease. Accordingly, by controlling the inflow rate of the oxygen gas serving as the control gas, the amount of CH═CH bonds may be controlled, and thus the extinction coefficient and the etching selectivity of the ACL may be controlled.

When carbon gas is used as the control gas, the carbon gas may be reacted with hydrogen in the deposition source gas, thereby decreasing the amount of CH═CH bonds in the ACL. Accordingly, by controlling the inflow rate of the carbon gas serving as the control gas, the amount of CH═CH bonds may be controlled, and thus the extinction coefficient and the etching selectivity of the ACL may be controlled.

When oxycarbon gas is used as the control gas, the ACL may be more uniformly formed.

Particularly, when the deposition process is performed in a plasma deposition chamber in which substrates having a diameter of about 200 mm may be used, the oxycarbon gas may be provided into the plasma deposition chamber at a flow rate of about 100 to about 300 sccm. When the deposition process is performed in a plasma deposition chamber in which substrates having a diameter of about 300 mm may be used, the oxycarbon gas may be provided into the plasma deposition chamber at a flow rate of about 1000 to about 1500 sccm.

As illustrated above, the ACL may be formed on a substrate having a large diameter without the substrate being bended. Additionally, the ACL may be formed to have a high uniformity at a high deposition rate. Furthermore, the ACL may have desired extinction coefficient and etching selectivity. Thus, the ACL may serve as a hard mask for forming minute patterns.

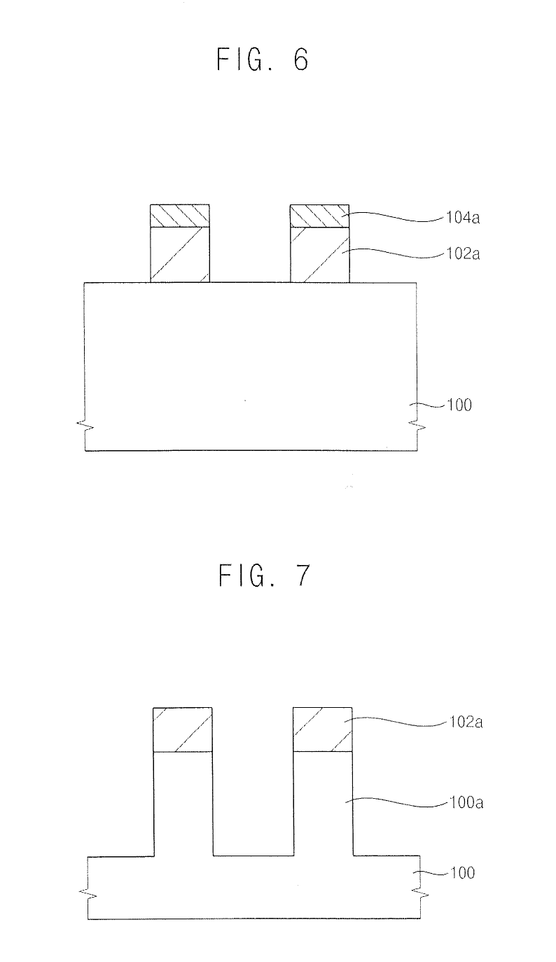

FIGS. 3 to 8 are cross-sectional views illustrating a method of forming a pattern in accordance with example embodiments. Particularly, a method of forming a single silicon pattern using the ACL as an etching mask in accordance with example embodiments may be illustrated.

Referring to FIG. 3, an amorphous carbon layer 102 may be formed on a substrate 100. The substrate 100 may include single crystalline silicon. The ACL 102 may serve as an etching mask for etching the substrate 100 in a subsequent process. Alternatively, an additional etching-target layer (not shown) may be formed on the substrate 100, and the ACL may be formed thereon. In this case, the etching-target layer may include silicon oxide (SiO), silicon nitride (SiN), silicon carbide (SiC), silicon carbo-nitride (SiCN), silicon oxynitride (SiON), etc. These may be used alone or in a combination thereof.

The ACL 102 may be formed on the substrate 100 by processes substantially the same as those illustrated with reference to FIGS. 1 and 2. Thus, the ACL 102 may be uniformly formed on the substrate 100, and the substrate 100 may remain uniform.

Referring to FIG. 4, a silicon oxynitride layer 104 may be formed on the ACL 102. The silicon oxynitride layer 104 may protect an unetched portion of the amorphous carbon 102 in a subsequent process. A bottom anti-reflective coating layer (BARC) 106 may be formed on the silicon oxynitride layer 104. A photoresist layer 108 may be formed on the BARC layer 106.

Referring to FIG. 5, the photoresist layer 108 may be patterned to form a photoresist pattern 108a by a photo process.

The BARC layer 106 and the silicon oxynitride layer 104 may be etched using the photoresist pattern 108a as an etching mask to form a BARC layer pattern 106a and a silicon oxynitride layer pattern 104a, respectively.

Referring to FIG. 6, the ACL 102 may be etched using the photoresist pattern 108a, the BARC layer pattern 106a and the silicon oxynitride layer pattern 104a as an etching mask to form an ACL pattern 102a. The ACL pattern 102a may have a uniform thickness because the ACL 102 may be formed uniformly.

When the etching process for forming the ACL pattern 102a is performed, the photoresist pattern 108a and the BARC layer pattern 106a having low etching resistance may be removed, and a portion of the silicon oxynitride layer pattern 104a may remain.

Referring to FIG. 7, the substrate 100 may be etched using the ACL pattern 102a and the silicon oxynitride layer pattern 104a as an etching mask to form a single crystalline silicon pattern 100a on the substrate 100.

As described above, the ACL pattern 102a may have a high etching selectivity with respect to single crystalline silicon, and thus may be proper as an etching mask for etching the single crystalline silicon substrate 100. That is, when the substrate 100 is etched, most of the ACL pattern 102a may remain. The ACL pattern 102a may be uniformly formed on the substrate 100, and thus the single crystalline silicon pattern 100a having a uniform shape may be formed on the substrate 100.

Referring to FIG. 8, the remaining portion of the ACL 102a may be removed. The removal may be performed, for example, by an ashing process and/or a stripping process.

According to example embodiments, the ACL pattern 102a may serve as a hard mask, and the substrate 100 may be uniformly etched using the hard mask to form the uniform single crystalline silicon pattern 100a thereon.

### Experiments of Stress of ACLs on Substrates

### Example 1

A first ACL was formed on a first substrate having a diameter of about 300 mm in accordance with example embodiments. The first ACL was formed by performing a plasma deposition process using C₃H₆ gas as a deposition source gas, helium gas as a carrier gas, and oxygen gas as a control gas at a temperature of about 450° C.

### Example 2

A second ACL was formed on a second substrate having a diameter of about 300 mm in accordance with example embodiments. The second ACL was formed by performing a plasma deposition process using C₃H₆ gas as a deposition source gas, helium gas as a carrier gas, and oxygen gas as a control gas at a temperature of about 400° C.

### Comparative Example 1

A third ACL was formed on a third substrate having a diameter of about 300 mm. The third ACL was formed by performing a plasma deposition process using C₃H₆ gas as a deposition source gas, helium gas as a carrier gas, and oxygen gas as a control gas at a temperature of about 300° C.

Stresses on the substrates of Examples 1 and 2 and Comparative Example 1 are shown in Table 1.

TABLE 1

| | Comparative | | |
|---|---|---|---|
| | Example 1 | Example 1 | Example 2 |
| Stress (MPa) | −300 | −170 | −40 |

As shown in Table 1, the first substrate of Comparative Example 1 is under a relatively high tensile stress, and the second and third substrates of Examples 2 and 3 are under a relatively low tensile stress.

### Experiments of Uniformity of ACLs

### Example 3

A fourth ACL was formed on a fourth substrate having a diameter of about 200 mm in accordance with example embodiments. The fourth ACL was formed by introducing C₃H₆ gas serving as a deposition source gas at a flow rate of about 165 sccm, helium gas serving as a carrier gas at a flow rate of about 100 sccm, and oxygen gas serving as a control gas at a flow rate of about 60 sccm at a temperature of about 450° C.

### Comparative Example 2

A fifth ACL was formed on a fifth substrate having a diameter of about 200 mm. The fifth ACL was formed by introducing C₃H₆ gas serving as a deposition source gas at a flow rate of about 165 sccm and helium gas serving as a carrier gas at a flow rate of about 100 sccm at a temperature of about 450° C. Oxygen gas was not introduced.

### Comparative Example 3

A sixth ACL was formed on a sixth substrate having a diameter of about 200 mm. The sixth ACL was formed by introducing C₃H₆ gas serving as a deposition source gas at a flow rate of about 700 sccm and helium gas serving as a carrier gas at a flow rate of about 225 sccm at a temperature of about 450° C. Oxygen gas was not introduced.

Thicknesses of the ACLs of Example 3 and Comparative Examples 2 and 3 were measured at various positions thereof. Particularly, thicknesses of each ACL at a left edge portion, a central portion and a right edge portion, respectively, were measured.

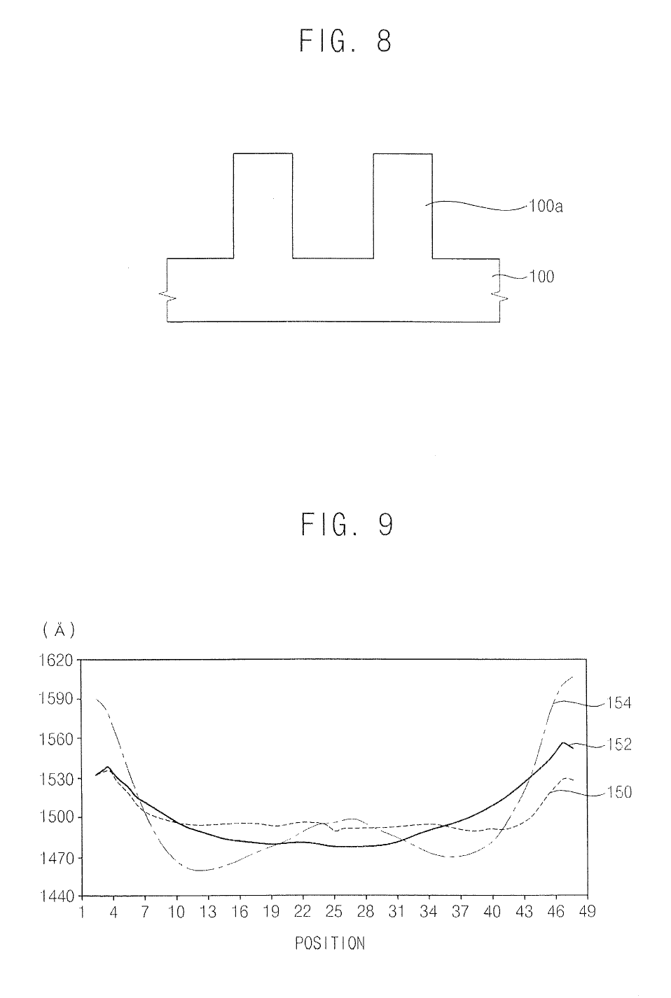

FIG. 9 is a graph showing the thicknesses of the ACLs of Example 3 and Comparative Examples 2 and 3. Reference numeral 150 indicates the thickness of the fourth ACL of Example 3, reference numeral 152 indicates the thickness of fifth ACL of Comparative Example 2, and reference numeral 154 indicates the thickness of sixth ACL of Comparative Example 3.

Referring to FIG. 9, the fourth ACL of Example 3 does not have a large difference between a thickness of the central portion and those of the edge portions, which means the fourth ACL was uniformly formed. The thickness difference of the sixth ACL between the central portion and the edge portions thereof in Comparative Example 3 was very large. In Comparative Example 3, a large amount of deposition gas was provided. Thus, the uniformity of the ACL may be deteriorated according as more deposition gas is provided.

### Analysis on Crystallization of ACLs

Raman spectroscopy was used for analyzing the crystallization of ACLs.

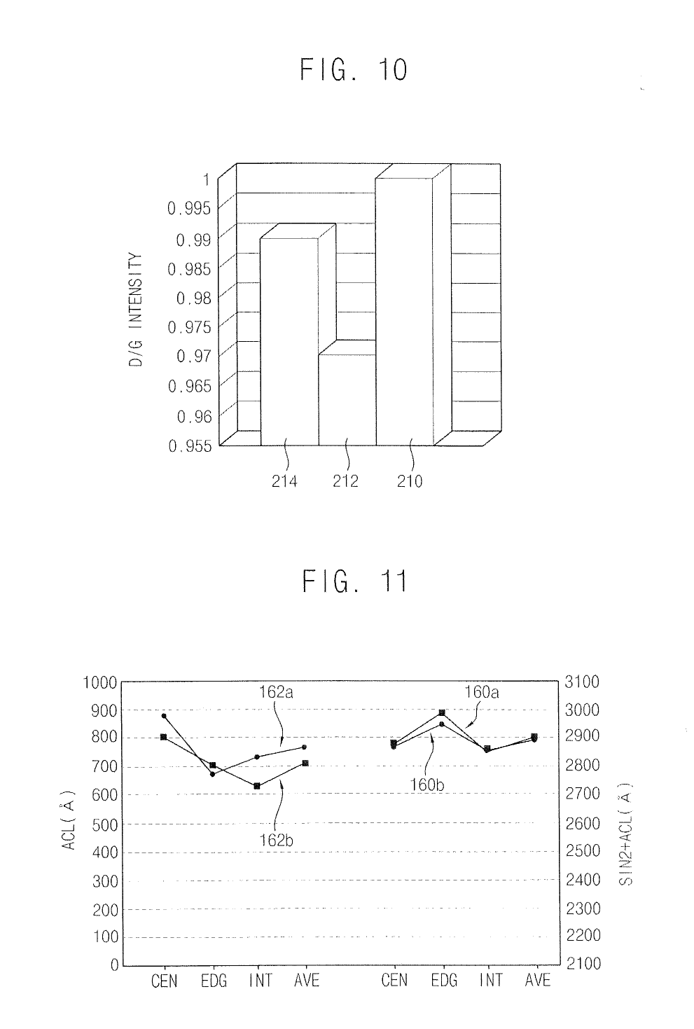

FIG. 10 is a graph showing the intensity of diamond/graphite (D/G) of the ACLs of Example 3 and Comparative Examples 2 and 3. Reference numeral 210 indicates the intensity of D/G of the fourth ACL of Example 3, reference numeral 212 indicates the intensity of D/G of the fifth ACL of Comparative Example 2, and reference numeral 214 indicates the intensity of D/G of the sixth ACL of Comparative Example 3.

Referring to FIG. 10, the fourth ACL of Example 3 has the highest intensity of D/G. The sixth ACL of Comparative Example 3 has a relatively high intensity of D/G, while the fifth ACL of Comparative Example 2 has the lowest intensity of D/G.

Accordingly, when a flow rate of the deposition gas decreases, the crystallization of the ACLs may decrease. However, when oxygen gas is provided as Example 3, the crystallization thereof may increase.

### Experiments on Characteristics of ACLs

### Example 4

A seventh ACL was formed on a seventh substrate having a diameter of about 300 mm in accordance with example embodiments. The seventh ACL was formed by introducing C₃H₆ gas serving as a deposition source gas at a flow rate of about 1200 sccm, helium gas serving as a carrier gas at a flow rate of about 1000 sccm, and oxygen gas serving as a control gas at a flow rate of about 90 sccm at a temperature of about 400° C.

### Example 5

A eighth ACL was formed on an eighth substrate having a diameter of about 300 mm in accordance with example embodiments. The eighth ACL was formed by introducing C₃H₆ gas serving as a deposition source gas at a flow rate of about 1200 sccm, helium gas serving as a carrier gas at a flow rate of about 1000 sccm, and carbon dioxide gas serving as a control gas at a flow rate of about 90 sccm at a temperature of about 400° C.

The characteristics of the seventh and eighth ACLs of Examples 4 and 5 are shown in Table 2.

TABLE 2

| | | Average | Thickness | |
|---|---|---|---|---|
| | Bend (μm) | Thickness (Å) | Range (Å) | Density (g/cc) |
| Example 4 | −64.29 | 7535 | 338 | 1.37 |
| Example 5 | −65.162 | 4313 | 126 | 1.35 |

As shown in Table 2, the seventh and eighth ACLs have good bending characteristics.

The thickness range means a difference between the largest thickness and the smallest thickness in each ACLs of Examples 4 and 5. Each seventh and eighth ACLs has a thickness range of about 5% of the average thickness, which means that each layer is formed uniformly. Particularly, the eighth ACL of Example 5 has a small thickness range of about 3% of the average thickness.

### Experiments on Etching Resistance of ACLs

### Example 6

A first silicon nitride layer was formed on a ninth substrate having a diameter of about 300 mm to have a thickness of about 2000 Å. A ninth ACL was formed on the first silicon nitride layer in accordance with example embodiments. The ninth ACL was formed by introducing C₃H₆ gas serving as a deposition source gas at a flow rate of about 1200 sccm, helium gas serving as a carrier gas at a flow rate of about 1000 sccm, and carbon oxide gas serving as a control gas at a flow rate of about 90 sccm at a temperature of about 400° C. The ninth ACL was patterned to form a ninth ACL pattern. The first silicon nitride layer was etched using the ninth ACL pattern as an etching mask to form a first silicon nitride layer pattern.

### Comparative Example 4

A second silicon nitride layer was formed on a tenth substrate having a diameter of about 300 mm to have a thickness of about 2000 Å. A tenth ACL was formed on the second silicon nitride layer. The tenth ACL was formed by introducing C₃H₆ gas serving as a deposition source gas at a flow rate of about 1200 sccm and helium gas serving as a carrier gas at a flow rate of about 1000 sccm at a temperature of about 400° C. The tenth ACL was patterned to form a tenth ACL pattern. The second silicon nitride layer was etched using the tenth ACL pattern as an etching mask to form a second silicon nitride layer pattern.

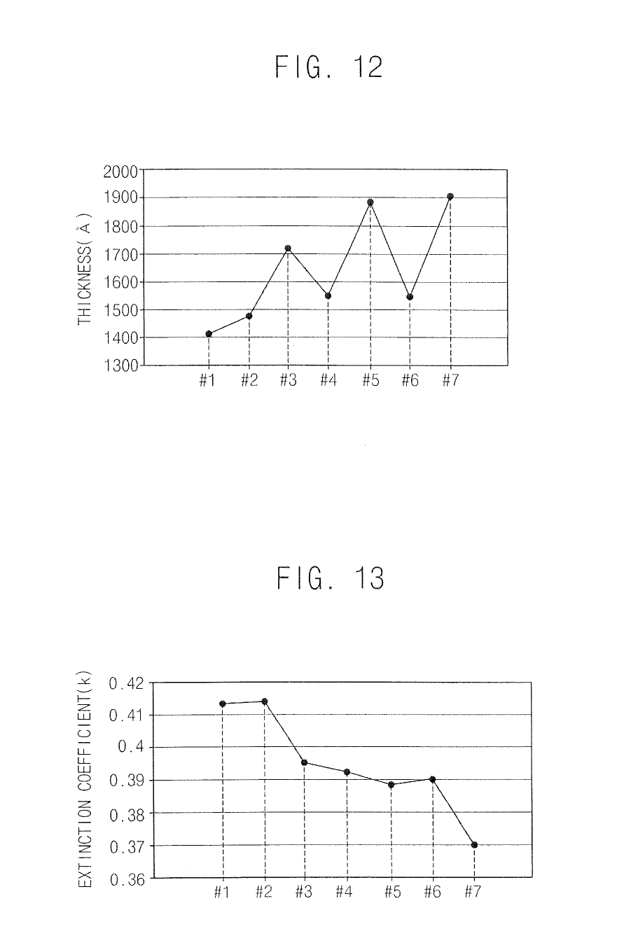

FIG. 11 is a graph showing thicknesses of the ACLs of Example 6 and Comparative Example 4 at various positions. Reference numeral 160a indicates thicknesses of the ninth ACL at a central portion, an edge portion and an intermediate portion therebetween, respectively, and an average thickness of the ninth ACL. Reference numeral 162a indicates thicknesses of the tenth ACL at a central portion, an edge portion and an intermediate portion therebetween, respectively, and an average thickness of the tenth ACL. Reference numeral 160b indicates sums of thicknesses of the ninth ACL and the first silicon nitride layer pattern at a central portion, an edge portion and an intermediate portion therebetween, respectively, and a sum of an average thickness of the ninth ACL and the first silicon nitride layer pattern. Reference numeral 162b indicates sums of thicknesses of the ninth ACL and the second silicon nitride layer pattern at a central portion, an edge portion and an intermediate portion therebetween, respectively, and a sum of an average thickness of the ninth ACL and the second silicon nitride layer pattern.

Referring to FIG. 11, after the etching process, the ninth ACL of Example 6 has a thickness of about 800 Å, while the tenth ACL of Comparative Example 4 has a thickness of about 700 Å. Additionally, after the etching process, the ninth ACL and the first silicon nitride layer pattern has a total thickness of about 2900 Å, while the tenth ACL and the second silicon nitride layer pattern has a total thickness of about 2800 Å.

Thus, the ninth ACL of Example 6 remains thicker than the tenth ACL of Comparative Example 4 after the etching process, which means the ninth ACL has a higher etching resistance than that of the tenth ACL. That is, an ACL that is formed using carbon oxide gas as a control gas may be proper for an etching mask.

Additionally, the ninth ACL has a less thickness difference than that of the tenth ACL at various positions thereof. The total thickness of the ninth ACL and the first silicon nitride layer pattern is smaller than that of the tenth ACL and the second silicon nitride layer pattern. The ninth ACL may be formed more uniformly that the tenth ACL at various positions thereof.

### Experiments on Deposition Rate and Extinction Coefficient of ACLs

### Comparative Example 5

Eleventh ACLs of Comparative Example 5 were formed on an eleventh substrate having a diameter of about 200 mm at various deposition gas conditions shown in Table 3, and thicknesses of the ACLs were measured. Oxygen gas was not included in the deposition gas.

TABLE 3

| | #1 | #2 | #3 | #4 | #5 | #6 | #7 |
|---|---|---|---|---|---|---|---|
| C₃H₆ (sccm) | 700 | 700 | 700 | 425 | 425 | 425 | 165 |
| He (sccm) | 150 | 225 | 500 | 78 | 325 | 572 | 100 |
| Total | 850 | 925 | 1200 | 503 | 750 | 997 | 265 |

### Deposition Gas

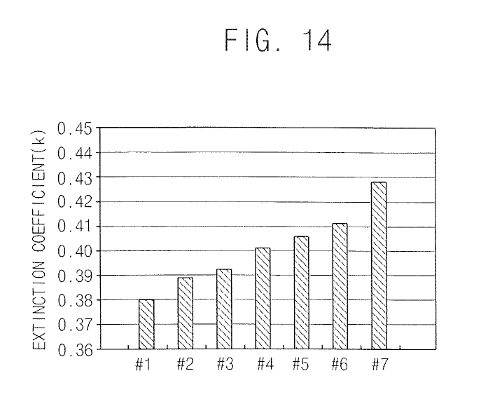

FIG. 12 is a graph showing thicknesses of the eleventh ACLs of Comparative Example 5 (#1 to #7).

Referring to FIG. 12, as a deposition source gas, i.e., C₃H₆ gas increases, the thickness of the eleventh ACLs, i.e., the deposition rate thereof decreases. When an amount of the C₃H₆ gas is the same, the thickness may change a little according to an amount of a carrier gas, i.e., helium gas. The deposition rate of the eleventh ACLs may increase according as the amount of the helium gas increases.

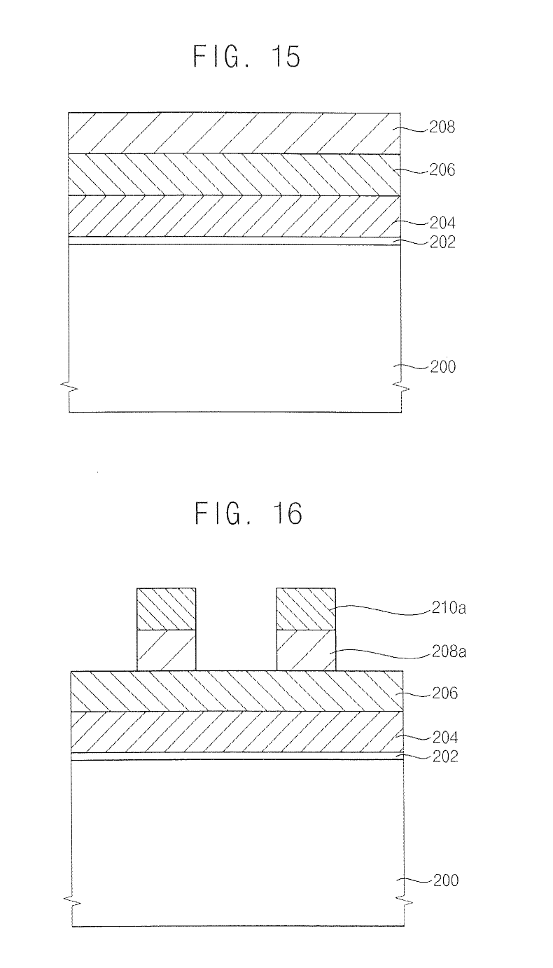

FIG. 13 is a graph showing the extinction coefficient of the eleventh ACLs of Comparative Example 5 (#1 to #7).

Referring to FIG. 13, as the deposition source gas, i.e., the C₃H₆ gas decreases, the extinction coefficient of the eleventh ACLs decreases.

As described above, when the deposition rate of the eleventh ACL is increased by reducing the amount of the C₃H₆ gas, the extinction coefficient thereof may decrease. For example, #7 ACL was formed by a high deposition rate of about 1900 Å/min, however, had a low extinction coefficient of about 0.37. Thus, the eleventh ACLs may not be proper as an etching mask.

### Example 7

Twelfth ACLs of Example 7 were formed on a twelfth substrate having a diameter of about 200 mm at various deposition gas conditions shown in Table 4, and thicknesses of the ACLs were measured.

TABLE 4

| | #1 | #2 | #3 | #4 | #5 | #6 | #7 |
|---|---|---|---|---|---|---|---|
| C₃H₆ (sccm) | 250 | 250 | 250 | 250 | 250 | 250 | 250 |
| He (sccm) | 220 | 220 | 220 | 220 | 220 | 220 | 220 |
| O₂ (sccm) | 15 | 20 | 30 | 40 | 50 | 60 | 70 |

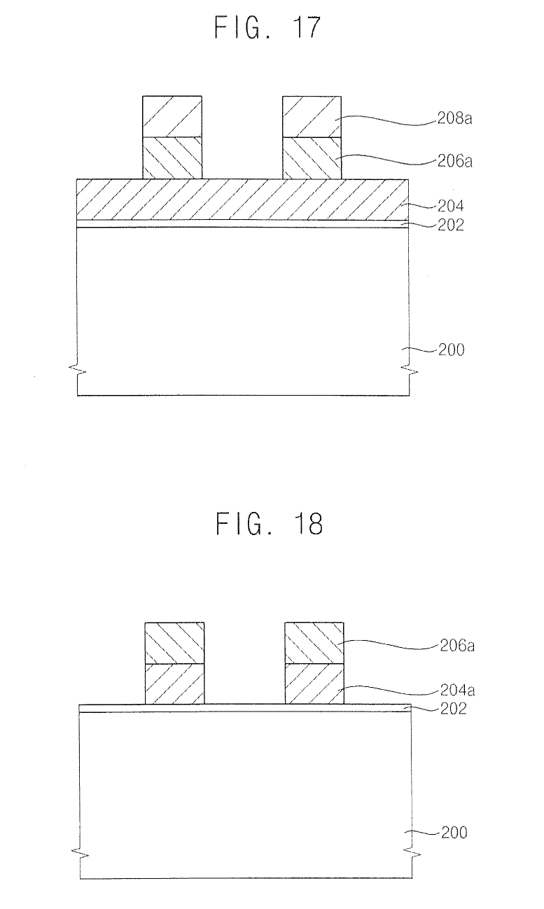

FIG. 14 is a graph showing the extinction coefficient of the twelfth ACLs of Example 7 (#1 to #7).

Referring to FIG. 14, as oxygen gas increases under a low flow rate of a deposition gas and a carrier gas, the extinction coefficient of the twelfth ACLs increases. Thus, by changing an amount of oxygen gas, the extinction coefficient of the twelfth ACLs may be controlled.

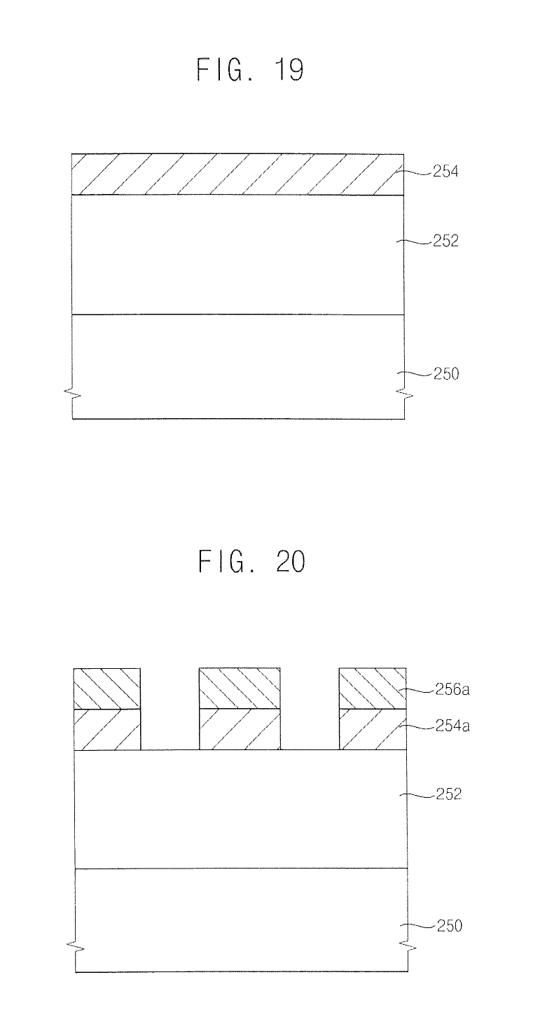

FIGS. 15 to 18 are cross-sectional views illustrating a method of forming a pattern in accordance with example embodiments. Particularly, a method of forming a gate electrode using the ACL as an etching mask in accordance with example embodiments may be illustrated.

Referring to FIG. 15, a gate insulation layer 202 and a gate conductive layer 204 may be formed on a substrate 200. The gate insulation layer 202 may be formed using silicon oxide. The gate conductive layer 204 may be formed using a semiconductor material such as polysilicon or a metal such as tungsten.

A silicon nitride layer 206 may be formed on the gate conductive layer 204. The silicon nitride layer 206 may serve as an etching mask for etching the gate conductive layer 204.

An amorphous carbon layer (ACL) 208 may be formed on the silicon nitride layer 206. The ACL 208 may serve as an etching mask for etching the silicon nitride layer 206. In the present embodiment, the silicon nitride layer 206 may serve as an etching-target layer.

The ACL 208 may be formed by processes substantially the same as those illustrated with reference to FIG. 2. Thus, when the ACL 208 is formed on the silicon nitride layer 206, the substrate 200 may not be bended. Additionally, the ACL 208 may have good uniformity.

Referring to FIG. 16, a silicon oxynitride layer and a bottom anti-reflective coating (BARC) layer (not shown) may be sequentially formed on the ACL 208. A photoresist pattern (not shown) may be formed on the BARC layer.

The BARC layer and the silicon oxynitride layer may be etched using the photoresist pattern as an etching mask to form a BARC layer pattern (not shown) and a silicon oxynitride layer pattern 210a, respectively.

The ACL 208 may be etched using the silicon oxynitride layer 210a as an etching mask to form an ACL pattern 208a on the silicon nitride layer 206. In the etching process, the photoresist pattern and the BARC layer pattern may be removed, and a portion of the silicon oxynitride layer pattern 210a may remain.

Referring to FIG. 17, the silicon nitride layer 206 may be etched using the ACL pattern 208a as an etching mask to form a silicon nitride layer pattern 206a on the gate conductive layer 204. The ACL pattern 208a may have a high etching resistance, so that most of the ACL pattern 208a may remain during the etching process. During the etching process, the remaining portion of the silicon oxynitride layer pattern 210a may be removed.

Referring to FIG. 18, the remaining ACL pattern 208a may be removed. The ACL pattern 208a may be removed by an ashing process and/or a stripping process.

The gate conductive layer 204 may be etched using the silicon nitride layer pattern 206a as an etching mask to form a gate electrode 204a. The gate electrode 204a may have a minute size.

The above processes may be applied to other conductive elements such as metal wirings or bitlines.

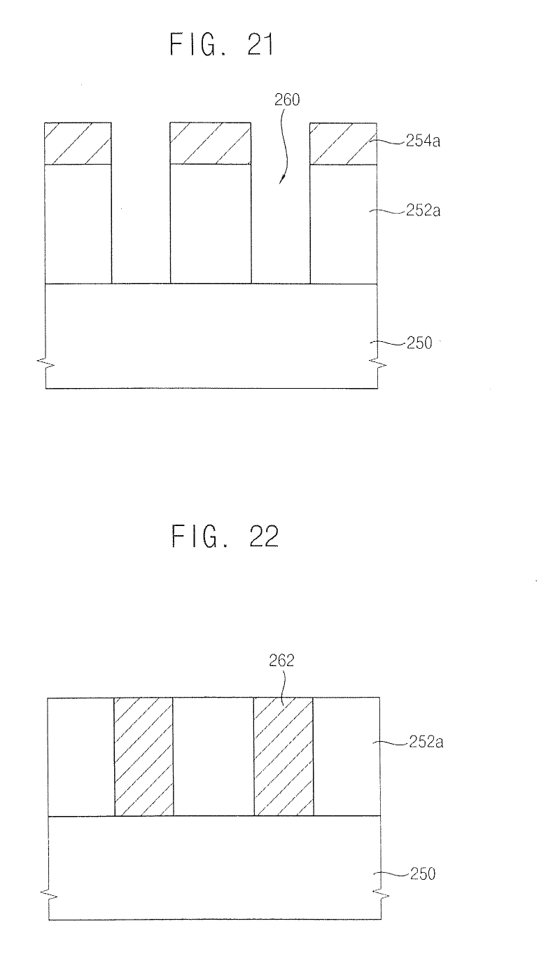

FIGS. 19 to 22 are cross-sectional views illustrating a method of forming a pattern in accordance with example embodiments. Particularly, a method of forming a contact plug through an insulating interlayer using the ACL as an etching mask in accordance with example embodiments may be illustrated.

Referring to FIG. 19, a substrate 250 having structures (not shown) such as devices or electrical elements thereon may be provided. For example, metal-oxide-semiconductor (MOS) transistors may be formed on the substrate 250.

An insulating interlayer 252 may be formed on the substrate 250. The insulating interlayer 252 may be formed using silicon oxide.

An ACL 254 may be formed on the insulating interlayer 252. The ACL 254 may be formed by processes substantially the same as those illustrated with reference to FIG. 2. The ACL 254 may serve as a hard mask for etching the insulating interlayer 252. In the present embodiment, the insulating interlayer 252 may serve as an etching-target layer.

Referring to FIG. 20, a silicon oxynitride layer and a BARC layer (not shown) may be formed on the ACL 254. A photoresist pattern (not shown) may be formed on the BARC layer. The photoresist pattern may have holes (not shown) therethrough.

The BARC layer and the silicon oxynitride layer may be etched using the photoresist pattern as an etching mask to form a BARC layer pattern (not shown) and a silicon oxynitride layer pattern 256a, respectively.

The ACL 254 may be etched using the silicon oxynitride layer pattern 256a as an etching mask to form an ACL pattern 254a. In the etching process, the photoresist pattern and the BARC layer pattern may be removed, and a portion of the silicon oxynitride layer pattern 256a may remain.

Referring to FIG. 21, the insulating interlayer 252 may be etched using the ACL pattern 254a as an etching mask to form contact holes 260 through the insulating interlayer 252. During the etching process, the remaining portion of the silicon oxynitride layer pattern 256a may be removed.

The ACL pattern 254a may have a high etching resistance, and thus the contact holes 260 having a minute size may be formed using the ACL pattern 254a as an etching mask.

Referring to FIG. 22, the remaining ACL pattern 254a may be removed. The ACL pattern 254a may be removed by an ashing process and/or a stripping process. A conductive material may be deposited in the contact holes 260, and an upper portion of the conductive material may be planarized until a top surface of the insulating interlayer 252a is exposed to form a plurality of contact plugs 262.

As described above, various kinds of patterns may be formed using the ACL pattern as an etching mask in various kinds of devices such as DRAM devices, SRAM devices, flash memory devices, PRAM devices, etc.

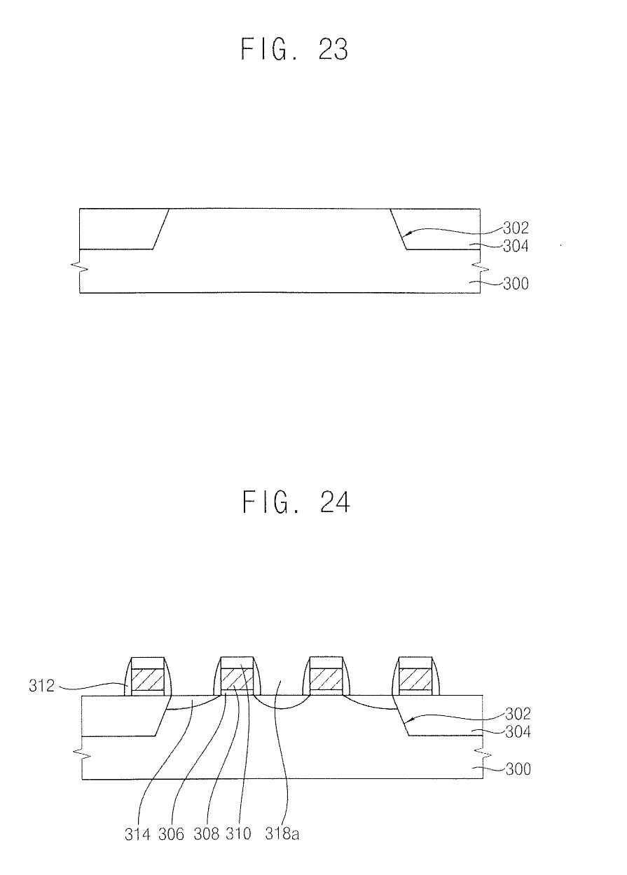

FIGS. 23 to 27 are cross-sectional views illustrating a method of manufacturing a DRAM device in accordance with example embodiments.

Referring to FIG. 23, an isolation layer 304 may be formed on a substrate 300 by a shallow trench isolation (STI) process.

Particularly, an ACL (not shown) may be formed on the substrate 300. An silicon oxynitride layer (not shown) and a BARC layer (not shown) may be formed on the ACL. The BARC layer and the silicon oxynitride layer may be patterned to form a BARC layer pattern (not shown) and a silicon oxynitride layer pattern (not shown), respectively. The ACL may be etched using the silicon oxynitride layer pattern as an etching mask to form an ACL pattern (not shown). The ACL pattern may cover an active region of the substrate 300.

The substrate 300 may be etched using the ACL pattern as an etching mask to form a trench 302 on the substrate 300. An insulating material may be deposited in the trench 202 to form the isolation layer 304.

Referring to FIG. 24, MOS transistors may be formed on the substrate 300. Particularly, processes substantially the same as those illustrated with reference to FIGS. 15 to 18 may be performed to form a plurality of gate structures of the MOS transistors. Each gate structure may include a gate insulation layer 306, a gate electrode 308 and a gate mask 310 sequentially stacked on the substrate 300. The gate electrode 308 may include a metal such as tungsten.

Gate spacers 312 may be formed on sidewalls of the gate structures. Impurity regions 314 may be formed at upper portions of the substrate 300 adjacent to the gate structures by implanting impurities onto the substrate 300. Thus, the MOS transistors may be formed.

Referring to FIG. 25, a first insulating interlayer 316 may be formed on the substrate 300 to cover the MOS transistors. The first insulating interlayer 316 may be partially removed to form a plurality of first contact holes 315 therethrough exposing the impurity regions 314. The first contact holes 315 may be formed by processes substantially the same as those illustrated with reference to FIGS. 19 to 21.

A first contact plug 318a and second contact plugs 318b may be formed on the substrate 300 to fill the first contact holes 315. The contact plugs 318a and 318b may be electrically connected to the impurity regions 314.

Referring to FIG. 26, a second insulating interlayer 320 may be formed on the first insulating interlayer 316 and the contact plugs 318a and 318b. The second insulating interlayer 320 may be partially removed to form a second contact hole 321 therethrough exposing the first contact plug 318a. The second contact hole 321 may be formed by processes substantially the same as those illustrated with reference to FIGS. 19 and 21.

A conductive layer may be formed on the first contact plug 318a and the second insulating interlayer 320 to fill the second contact hole 321. The conductive layer may be patterned to form a bitline 322b and a bitline contact plug 322a. The conductive layer may be patterned by processes similar to those illustrated with reference to FIGS. 15 to 18. A third insulating interlayer 324 may be formed on the second insulating interlayer 320 to cover the bitline 322b.

The third insulating interlayer 324 may be partially removed to form third contact holes 325 therethrough exposing the second contact plugs 318b. Storage contact plugs 326 may be formed on the second contact plugs 318b to fill the third contact holes 325. The storage contact plugs 326 may be formed by processes substantially the same as those illustrated with reference to FIGS. 19 to 22.

Referring to FIG. 27, a mold layer (not shown) may be formed on the third insulating interlayer 324 and the storage contact plugs 326. The mold layer may be partially removed to form openings (not shown) therethrough exposing the storage contact plugs 326. The openings may be formed by processes substantially the same as those illustrated with reference to FIGS. 19 to 21.

A lower electrode layer may be formed on the storage contact plugs 326 and the mold layer. The lower electrode layer may be formed using doped polysilicon, a metal or a metal nitride. For example, the lower electrode may be formed using doped polysilicon, titanium, tantalum, tungsten, ruthenium, titanium nitride, tantalum nitride, tungsten nitride, etc. These may be used alone or in a combination thereof.

A sacrificial layer (not shown) may be formed on the lower electrode to fill the remaining portion of the openings. Upper portions of the sacrificial layer and the lower electrode layer may be planarized until a top surface of the mold layer is exposed to form a plurality of lower electrodes 328 on inner walls of the openings. The sacrificial layer and the mold layer may be removed.

A dielectric layer 330 and an upper electrode 332 may be sequentially formed on the lower electrode 328 and the third insulating interlayer 324. Thus, a capacitor including the lower electrode 328, the dielectric layer 330 and the upper electrode 332 may be formed.

As illustrated above, the DRAM device including patterns having minute sizes may be manufactured.

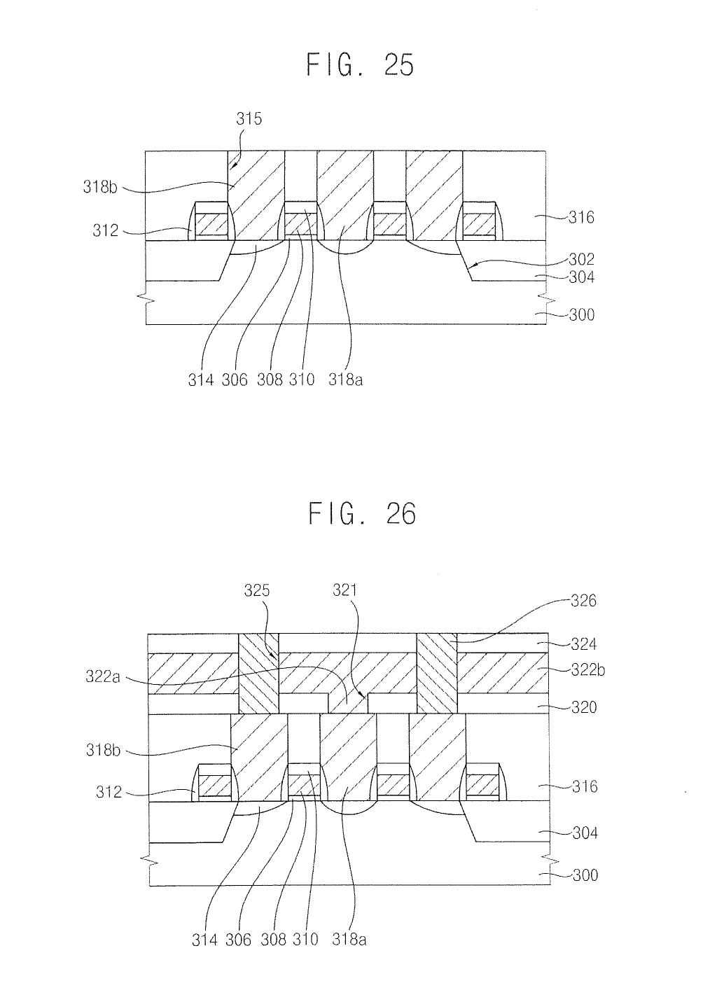

FIG. 28 is a block diagram illustrating a memory card including the ACL formed by the method in accordance with example embodiments.

Referring to FIG. 28, a memory card 630 may include a memory controller 620 connected to a memory 610. The memory 610 may be a DRAM or a flash memory (an NAND flash memory or an NOR flash memory) having the ACL formed by the method in accordance with example embodiments. The memory controller 620 may provide the memory 610 with input signals to control operations of the memory 610. For example, in the memory card 630, the memory controller 620 may transfer commands of a host to the memory 610 to control input/output data and/or may control various data of a memory based on an applied control signal. In addition to a simple memory card, the present invention may be applied to other digital devices which include a similar operative association between a memory and a memory controller.

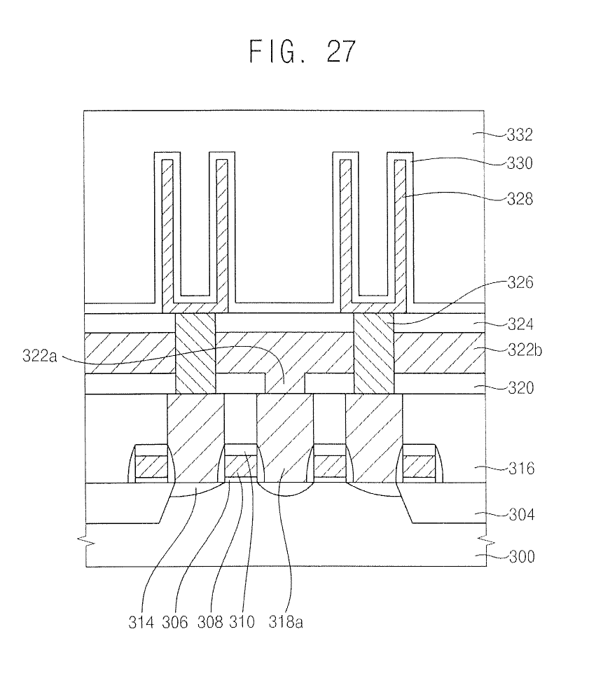

FIG. 29 is a block diagram illustrating a portable device including the ACL formed by the method in accordance with example embodiments.

Referring to FIG. 29, a portable device 700 may include an MP3 player, a video player, or a portable multi-media player (PMP). The portable device 700 may include a memory 610 having the ACL according to example embodiments, and a memory controller 620 as described above. The memory 610 may be a DRAM or flash memory including the ACL.

The portable device 700 may include an encoder/decoder (EDC) 710, a display element 720 and an interface 730. As illustrated by the dashed lines of FIG. 29, data may be directly input from the EDC 710 to the memory 610, or directly output from the memory 610 to the EDC 710.

The EDC 710 may encode data to be stored in the memory 610. For example, the EDC 710 may execute encoding for storing audio data and/or video data in the memory 610 of an MP3 player or a PMP player. Furthermore, the EDC 710 may execute MPEG encoding for storing video data in the memory 610. The EDC 710 may include multiple encoders to encode different types of data depending on their formats. For example, the EDC 710 may include an MP3 encoder for encoding audio data and an MPEG encoder for encoding video data.

The EDC 710 may also decode data being output from the memory 610. For example, the EDC 710 may decode MP3 audio data from the memory 610. Furthermore, the EDC 710 may decode MPEG video data from the memory 610. The EDC 710 may include multiple decoders to decode different types of data depending on their formats. For example, the EDC 710 may include an MP3 decoder for audio data and an MPEG decoder for video data.

The EDC 710 may include only a decoder. For example, encoded data may be input to the EDC 710, and then the EDC 710 may decode the input data and transfer the decoded data to the memory controller 620 or the memory 610.

The EDC 710 may receive data to be encoded or data being encoded by way of the interface 730. The interface 730 may be compliant with standard input devices, e.g. FireWire, or an USB. That is, the interface 730 may include a FireWire interface, an USB interface or the like. Data is output from the memory 610 by way of the interface 730.

The display element 720 may display to an end user data output from the memory 610 and decoded by the EDC 710. For example, the display element 720 may be an audio speaker or a display screen.

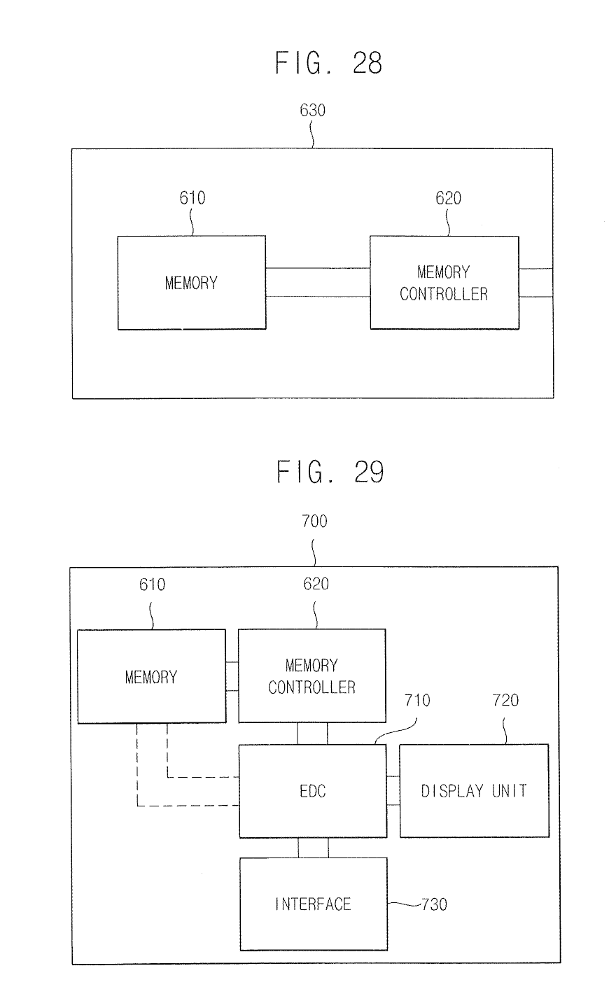

FIG. 30 is a block diagram illustrating a computer including the ACL formed by the method in accordance with example embodiments.

Referring to FIG. 30, a computer 800 may include a memory 610 and a central processing unit (CPU) 810 connected to the memory 610. The memory 610 may be a DRAM or a flash memory having the ACL in accordance with example embodiments. An example of such a computer 800 may be a laptop computer including a flash memory as its main memory. The memory 610 may be directly connected to the CPU 810, or indirectly connected to the CPU 810 by buses. The computer 800 may have other conventional auxiliary devices (not illustrated in FIG. 30).

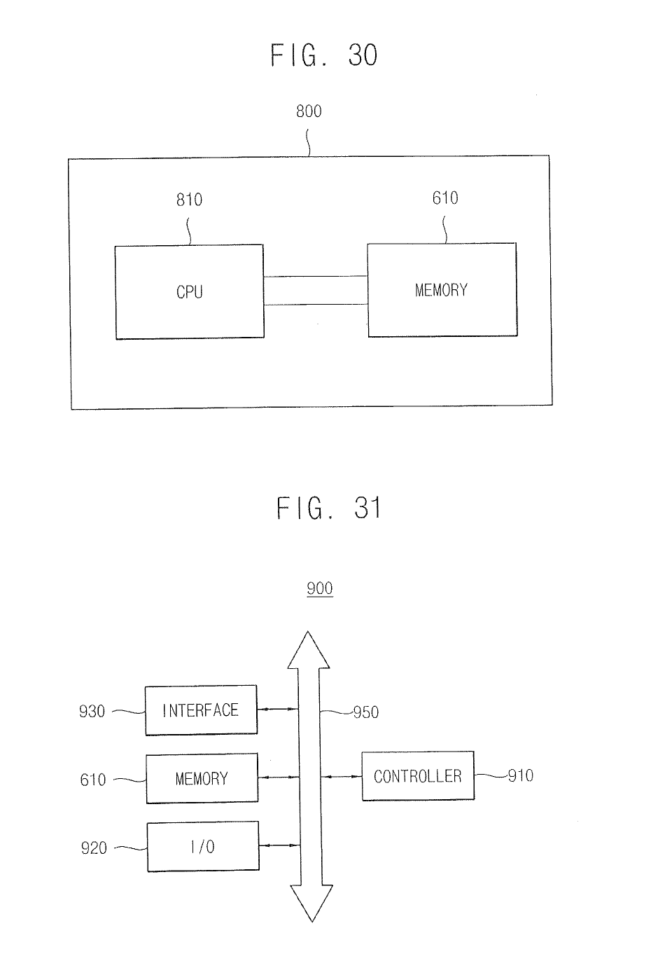

FIG. 31 is a block diagram illustrating a semiconductor device including the ACL formed by the method in accordance with example embodiments.

Referring to FIG. 31, a semiconductor device 900 may include a controller 910, an input/output unit 920, an interface 930 and a memory 610. The interface 930 may include a keyboard, display unit, etc. The elements of the semiconductor device 900 may be connected to each other by bus 950. The controller 910 may include a microprocessor, digital processor, a microcontroller, etc. The memory 610 may include the ACL in accordance with example embodiments. The memory 610 may store data and/or orders executed by the controller 910. Data may be transferred to other systems such as communication networks via the interface 930. The semiconductor device 900 may include a PDA, a portable computer, a web tablet, a wireless phone, a cell phone, a digital music player, a memory card, etc.

According to example embodiments, an ACL having a good uniformity and a controllable etching selectivity may be formed on a substrate without bending the substrate. The ACL may serve as an etching mask or a hard mask for forming minute patterns.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an amorphous carbon layer (ACL), comprising:
providing a substrate in a deposition chamber; and
performing a plasma deposition process by providing a deposition gas into the deposition chamber to form the ACL on the substrate, the deposition gas including a deposition source gas, a carrier gas and a control gas, the deposition source gas including hydrocarbon, and the control gas including at least one of oxygen and oxycarbon.

2. The method of claim 1, wherein the deposition gas is provided into the deposition chamber at a flow rate per hour of about 1 to about 20% of a volume of the deposition chamber.

3. The method of claim 1, wherein the deposition source gas and the control gas are provided into the deposition chamber at a flow rate ratio of about 20:1 to about 2:1.

4. The method of claim 3, wherein the deposition source gas and the control gas are provided into the deposition chamber at a flow rate ratio of about 5:1 to about 2:1.

5. The method of claim 1, wherein the hydrocarbon includes carbon and hydrogen at a ratio of about 1:2 to about 1:5.

6. The method of claim 1, wherein a temperature of the substrate is controlled so that the substrate remains flat.

7. The method of claim 6, wherein the substrate is maintained at a temperature of about 400 to about 500° C.

8. The method of claim 7, wherein the substrate is maintained at a temperature of about 430 to about 470° C.

9. The method of claim 1, wherein the oxycarbon includes carbon monoxide or carbon dioxide.

10. The method of claim 1, wherein an amount of the control gas is controlled so that an extinction coefficient of the ACL is controlled.

11. The method of claim 10, wherein the amount of the control gas is increased so that the extinction coefficient of the ACL increases, or an amount of the oxygen in the control gas is decreased so that the extinction coefficient of the ACL decreases.

12. The method of claim 1, wherein the substrate has a diameter of about 300 nm.

13. The method of claim 12, wherein the control gas includes oxycarbon gas, and the oxycarbon gas is provided in the deposition chamber at a flow rate of about 1000 to about 1500 sccm.

14. A method of forming a pattern, comprising:
providing a substrate in a deposition chamber, the substrate having an etching-target layer thereon;
performing a plasma deposition process at a temperature of about 400 to about 500° C. by providing a deposition gas into the deposition chamber to form an amorphous carbon layer (ACL) on the etching-target layer, the deposition gas including a deposition source gas, a carrier gas and a control gas, the deposition source gas including hydrocarbon, and the control gas including at least one of oxygen and oxycarbon;
forming a photoresist pattern on the ACL;
partially etching the ACL using the photoresist pattern to form an ACL pattern; and
partially etching the etching-target layer using the ACL pattern to form the pattern.

15. The method of claim 14, wherein the etching-target layer comprises at least one selected from the group consisting of silicon oxide, silicon nitride, single crystalline silicon, silicon oxycarbide, and silicon oxynitride.

16. The method of claim 14, wherein the deposition gas is provided into the deposition chamber at a flow rate per hour of about 1 to about 20% of a volume of the deposition chamber.

17. The method of claim 14, wherein the deposition source gas and the control gas are provided into the deposition chamber at a flow rate ratio of about 20:1 to about 2:1.

18. The method of claim 14, wherein the hydrocarbon includes carbon and hydrogen at a ratio of about 1:2 to about 1:5.

19. The method of claim 1, wherein the oxycarbon includes carbon monoxide or carbon dioxide.

20. The method of claim 1, wherein an amount of the control gas is controlled so that an extinction coefficient of the ACL is controlled.
